(19) United States
(12) Patent Application Publication
(10) Pub. No.: US 2025/0259963 A1
(43) Pub. Date: Aug. 14, 2025

(54) WIRE BONDING APPARATUS, CONTROL DEVICE, AND CONTROL METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Masatoshi TANABE, Yokohama (JP); Akira TOJO, Naka (JP); Yasunari UKITA, Kamakura (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/034,920

(22) Filed: Jan. 23, 2025

(30) Foreign Application Priority Data
Feb. 8, 2024 (JP) 2024-018071

(51) Int. Cl. H01L 23/00; H01L 21/66

(52) U.S. Cl. CPC H01L 24/78; H01L 22/12; H01L 2224/78841; H01L 2224/78901; H01L 2924/40

(57) ABSTRACT

According to one embodiment, a wire bonding apparatus includes a bonding tool configured to feed a wire, a driver configured to drive the bonding tool, and a controller. The controller performs a bonding process of causing a ball formed at a tip of the wire to contact a first bonding point, deforming the ball into a bump, and bonding the bump to the first bonding point. The controller further performs a lowering process of raising the bonding tool while the bonding tool holds the wire connected with the bump, changing a position of the bonding tool in a horizontal direction, and subsequently lowering the bonding tool toward the first bonding point. The controller determines a goodness of the bonding of the bump to the first bonding point based on a detected value detected in the lowering process, the detected value being prescribed.

### CROSS-REFERENCE TO RELATED APPLICATIONS

This application is based upon and claims the benefit of priority from Japanese Patent Application No. 2024-018071, filed on Feb. 8, 2024; the entire contents of which are incorporated herein by reference.

### FIELD

Embodiments of the invention generally relate to a wire bonding apparatus, a control device, and a control method.

### BACKGROUND

used in Wire bonding apparatuses are widely manufacturing processes of semiconductor devices. A wire bonding apparatus forms a bump, bonds a wire, etc. There is a need for wire bonding apparatus technology that can determine the goodness of the bump bonding at an earlier timing.

### BRIEF DESCRIPTION OF THE DRAWINGS

FIG. 1 is a schematic view schematically showing a wire bonding apparatus according to an embodiment;

FIG. 2 is a schematic view schematically showing a portion of the wire bonding apparatus according to the embodiment;

FIGS. 3A to 3C are schematic views showing an example of a wire bonding process;

FIG. 4 is a schematic view showing an example of a bump bonding process;

FIG. 5 is a schematic view showing the change of the Z-position of a bonding tool;

FIG. 6A is a schematic view showing the state of a bump when the bonding is good, and FIG. 6B is a schematic view showing the state of the bump when the bonding is defective;

FIG. 7 is a schematic view showing another example of the bump bonding process;

FIG. 8 is a schematic view showing the change of the Z-position of the bonding tool;

FIG. 9 is a schematic view showing an example of the bump bonding process;

FIG. 10 is a schematic view showing the change of the load on the bonding tool;

FIG. 11 is a schematic view showing the change of the Z-position of the bonding tool; and

FIG. 12 is a schematic view illustrating a hardware configuration.

### DETAILED DESCRIPTION

According to one embodiment, a wire bonding apparatus includes: a bonding tool configured to feed a wire; a driver configured to drive the bonding tool; and a controller configured to control the bonding tool and the driver. The controller performs a bonding process of causing a ball formed at a tip of the wire to contact a first bonding point, deforming the ball into a bump, and bonding the bump to the first bonding point. The controller further performs a lowering process of raising the bonding tool while the bonding tool holds the wire connected with the bump, changing a position of the bonding tool in a horizontal direction, and subsequently lowering the bonding tool toward the first bonding point. The controller determines a goodness of the bonding of the bump to the first bonding point based on a detected value detected in the lowering process, the detected value being prescribed.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

Embodiments of the invention relate generally to a wire bonding apparatus, a control device controlling the apparatus, and a control method of the apparatus. For example, the wire bonding apparatus is used in a manufacturing process of a semiconductor device and uses a wire, which is a fine metal wire, to connect between a pad, which is an electrode of a semiconductor chip, and a lead, which is an electrode of a leadframe.

### First Embodiment

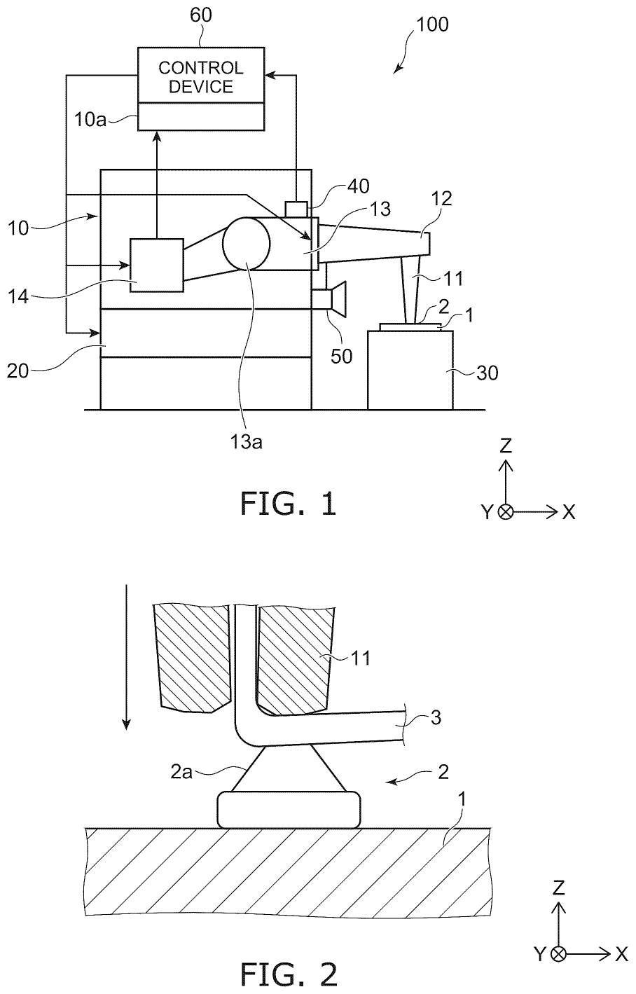

FIG. 1 is a schematic view schematically showing a wire bonding apparatus according to an embodiment.

As shown in FIG. 1, the wire bonding apparatus 100 according to the embodiment includes a bonding head 10, a position detecting part 10a, an X-Y stage 20, a bonding stage 30, a load sensor 40, a camera device 50, and a controller 60.

The bonding head 10 includes a bonding tool 11, an ultrasonic horn 12, a bonding arm 13, and a driver 14.

The bonding tool 11 feeds a wire 3 as a bonding material. The bonding tool 11 is, for example, a bonding capillary. The wire 3 is, for example, an aluminum wire, a gold wire, a silver wire, a copper wire, etc. The bonding tool 11 causes the wire 3 to contact a bonding portion 2 of a workpiece 1 placed on the bonding stage 30, and applies a load to the bonding portion 2. According to the embodiment, the bonding portions 2 include a first bonding point P1 or a second bonding point P2 which are described below.

The position detecting part 10a detects the Z-direction position of the bonding tool 11. For example, an origin is defined at a prescribed position; and the position detecting part 10a detects the vertical-direction position of the bonding tool 11 from the origin. The position detecting part 10a is communicably connected with the controller 60.

The ultrasonic horn 12 generates an ultrasonic vibration. The ultrasonic horn 12 includes an ultrasonic vibrator that generates the ultrasonic vibration. The ultrasonic horn 12 supports the bonding tool 11. The ultrasonic vibration that is generated from the ultrasonic horn 12 is transferred to the wire 3 via the bonding tool 11. The wire 3 is bonded to the bonding portion 2 by the ultrasonic vibration being transferred to the wire 3 in a state in which the wire 3 contacts the bonding portion 2. The ultrasonic horn 12 is electrically connected with the controller 60.

The bonding arm 13 supports the ultrasonic horn 12. That is, the bonding arm 13 supports the bonding tool 11 via the ultrasonic horn 12. The bonding arm 13 is rotatable around an axis part 13a.

The driver 14 drives the bonding arm 13 in a Z-direction with the axis part 13a as the center. The driver 14 is, for example, a linear motor. The bonding tool 11 and the ultrasonic horn 12 that are supported by the bonding arm 13 are moved in the Z-direction by moving the bonding arm 13 in the Z-direction. By moving the bonding tool 11 in the Z-direction, the wire 3 can be caused to contact the first bonding point P1 or the second bonding point P2 described below; and the load can be applied from the bonding tool 11. The driver 14 is communicably connected with the controller 60.

In this specification, the direction that connects the bonding tool 11 and the workpiece 1 is taken as the Z-direction. A direction orthogonal to the Z-direction is taken as an X-direction. A direction orthogonal to the Z-direction and X-direction is taken as a Y-direction. For example, the Z-direction is parallel to the vertical direction. The X-direction and the Y-direction are parallel to the horizontal plane. Herein, the direction from the bonding tool 11 toward the workpiece 1 is called “down”, and the opposite direction of down is called “up”.

The bonding head 10 is mounted to the X-Y stage 20. The X-Y stage 20 is movable in the X-direction and Y-direction. The bonding head 10 is moved in the X-direction and Y-direction by moving the X-Y stage 20 in the X-direction and Y-direction. That is, the X-Y stage 20 functions as a positioning part that positions the bonding tool 11 and the like included in the bonding head 10 in the X-direction and Y-direction. The X-Y stage 20 is communicably connected with the controller 60.

The bonding stage 30 supports the workpiece 1, which is the object of the wire bonding. For example, the bonding stage 30 supports the workpiece 1 by suction. The workpiece 1 is a substrate or a semiconductor chip such as an IC chip, etc.

The load sensor 40 continuously detects the load applied from the bonding portion 2 of the workpiece 1 to the bonding tool 11. The load sensor 40 includes, for example, a strain gauge. In the illustrated example, the load sensor 40 is mounted to the bonding arm 13. The load sensor 40 is communicably connected with the controller 60. The load sensor 40 outputs data of the detected load to the controller 60.

The camera device 50 images the ball formed at the tip of the bonding tool 11. Parameters of the ball can be calculated based on the image acquired by the camera device 50.

The controller 60 controls operations of the bonding tool 11, the ultrasonic horn 12, the driver 14, and the X-Y stage 20. For example, the controller 60 controls the feeding of the wire by the bonding tool 11 and the supply rate of the wire. The controller 60 controls the output of the ultrasonic vibration generated from the ultrasonic horn 12.

The controller 60 can move the bonding tool 11 by operating the driver 14. More specifically, the controller 60 can control the Z-direction position of the bonding tool 11 by driving the bonding arm 13 in the Z-direction by controlling the driver 14. As a result, the controller 60 can control the magnitude of the load applied from the bonding tool 11 to the bonding portion 2.

The position detecting part 10a acquires the Z-direction position of the bonding tool 11 driven by the driver 14. The position detecting part 10a may be included in the controller 60. For example, the position detecting part 10a includes an encoder. When a motor of the driver 14 is operated, the position detecting part 10a detects the rotational direction and rotational position of the motor. The position detecting part 10a calculates the Z-direction position of the bonding tool 11 based on the detected rotational direction and position.

The controller 60 can move the bonding tool 11 by operating the X-Y stage 20. More specifically, the controller 60 can control the positions of the bonding tool 11 in the X-direction and Y-direction by driving the bonding head 10 in the X-direction and Y-direction by controlling the X-Y stage 20.

FIG. 2 is a schematic view schematically showing a portion of the wire bonding apparatus according to the embodiment.

As shown in FIG. 2, a bump 2a is formed at the bonding portion 2 of the workpiece 1; and the wire 3 is bonded to the bump 2a. The wire bonding apparatus 100 forms the bump 2a, bonds the wire 3 to the bump 2a, etc. For example, the wire bonding apparatus 100 bonds the wire 3 to the bonding portion 2 by generating an ultrasonic vibration from the ultrasonic horn 12 in a state in which the wire 3 is fed from the bonding tool 11 and pressed onto the bonding portion 2.

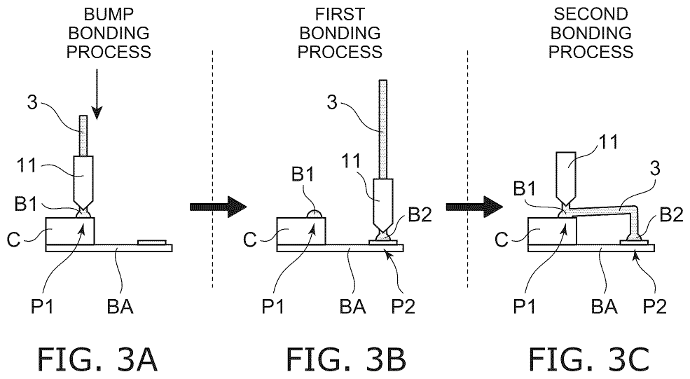

A series of processes of bonding the wire 3 will now be described. FIGS. 3A to 3C are schematic views showing an example of a wire bonding process.

As shown in FIGS. 3A to 3C, the wire bonding process includes the three processes of a bump bonding process (FIG. 3A), a first bonding process (FIG. 3B), and a second bonding process (FIG. 3C). In the illustrated example, a chip C is located on a substrate BA. The first bonding point P1 is on the chip C; and the second bonding point P2 is on the substrate BA. The substrate BA on which the chip C is located is an example of the workpiece 1. The first bonding point P1 and the second bonding point P2 each are examples of the bonding portion 2. Bumps B1 and B2 are formed at the first and second bonding points P1 and P2; and the wire 3 is bonded to the bumps.

First, as shown in FIG. 3A, the bump bonding process is performed to form the bump B1 at the first bonding point P1. Specifically, the bonding tool 11 moves above the first bonding point P1 of the chip C. The wire 3 is inserted into the bonding tool 11; and the tip of the wire 3 is pre-formed into a ball. For example, the tip of the wire is melted by generating an electrical discharge at the tip of the wire by applying a voltage to the wire. A ball is formed by the molten metal rounding into a sphere due to surface tension and then solidifying. The bonding tool 11 is lowered toward the first bonding point P1; and the ball at the tip of the wire 3 contacts the first bonding point P1. An ultrasonic wave is applied to the bonding tool 11 in a state in which a load is applied to the wire 3. As a result, the ball at the tip of the wire 3 is deformed into the bump B1 on the chip C; and the bump B1 is bonded with the first bonding point P1. Subsequently, the wire 3 is cut by an ultrasonic wave; and the bump B1 remains on the chip C. Then, the bonding tool 11 moves above the second bonding point P2 from the first bonding point P1.

After forming the bump B1, the first bonding process is performed as shown in FIG. 3B. A ball is pre-formed at the tip of the wire 3. The bonding tool 11 is lowered toward the second bonding point P2; and the ball at the tip of the wire 3 contacts the second bonding point P2. An ultrasonic wave is applied to the bonding tool 11 in a state in which a load is applied to the wire 3. As a result, the ball at the tip of the wire 3 is deformed into the bump B2 on the substrate BA; and the bump B2 is bonded with the second bonding point P2. After forming the bump B2, the wire 3 is not cut; and the state in which the wire 3 is connected with the bump B2 is maintained.

After forming the bump B2, the second bonding process is performed as shown in FIG. 3C. The bonding tool 11 moves upward for a prescribed distance in the state in which the bump B2 and the wire 3 are connected. Subsequently, the bonding tool 11 bends the wire 3 and moves toward the first bonding point P1 from the second bonding point P2. The wire 3 is bonded with the bump B1 on the chip C. Then, the wire 3 is cut by an ultrasonic vibration; and the wire 3 is bonded to the chip C and the substrate BA. The procedure described above is an example of wire bonding.

The procedure is not limited to the illustrated example; the first bonding point may be positioned on the substrate BA; and the second bonding point may be positioned on the chip C. In such a case, the bump B1 is formed on the substrate BA, then the bump B2 is formed on the chip C, and the wire 3 is bonded from the bump B2 to the bump B1.

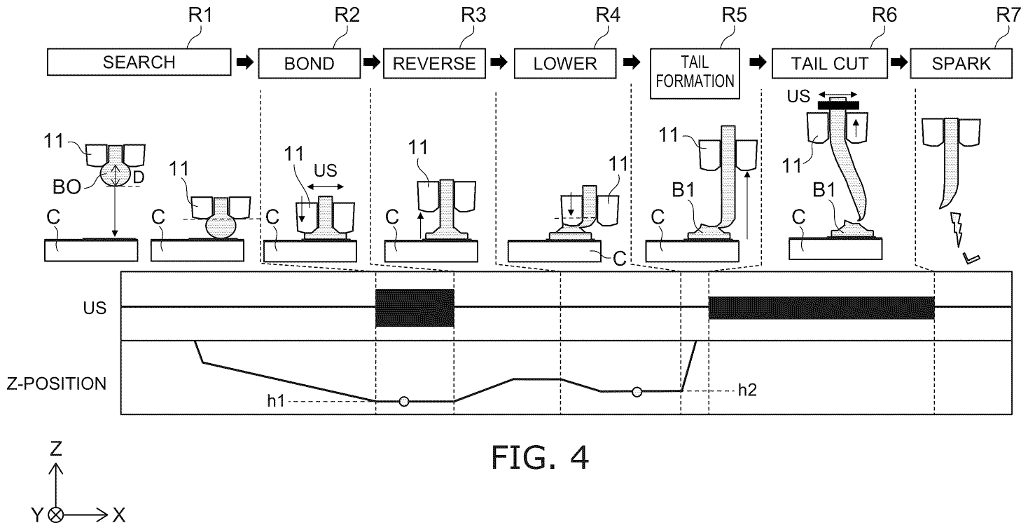

The bump bonding process will now be described in more detail. FIG. 4 is a schematic view showing an example of the bump bonding process.

As shown in FIG. 4, the bump bonding process includes a search process R1, a bonding process R2, a reverse process R3, a lowering process R4, a tail formation process R5, a tail cut process R6, and a spark process R7.

In the search process R1, a ball BO that is formed at the tip of the wire 3 inserted into the bonding tool 11 is caused to contact the surface of the chip C. In the bonding process R2, the ball BO is mashed and bonded to the surface of the chip C by applying a load and an ultrasonic vibration to the ball BO. In the reverse process R3, after the bonding tool 11 is raised a prescribed distance, the position of the bonding tool 11 in the horizontal direction is changed. In the lowering process R4, the height of the bump B1 is determined by lowering the bonding tool 11. In the reverse process R3 and the lowering process R4, the wire remains connected with the bump. In the tail formation process R5, the bonding tool 11 is raised to a prescribed position to form a tail. The tail cut process R6 cuts the tail away from the bump B1 by applying an ultrasonic vibration while raising the bonding tool 11. As a result, the bump B1 is formed on the chip C. In the following spark process R7, a ball is formed at the tip of the wire 3 by melting the tip of the wire 3 by generating a spark at the tip of the wire 3.

FIG. 4 also shows the vibration state of the ultrasonic vibration (US) and the detection state of the Z-position of the bonding tool 11 in the processes R1 to R7. In FIG. 4, h1 illustrates the Z-direction position when the bonding tool 11 is lowered most in the bonding process R2. For example, in the bonding process R2, the bonding tool 11 is lowered until a prescribed load on the bonding tool 11 is detected. Or, the bonding tool 11 is lowered until the lowering rate of the bonding tool 11 reaches or drops below a prescribed value. h2 illustrates the Z-position when the bonding tool 11 is lowered until a prescribed load is applied to the bonding tool 11 in the lowering process R4, or the Z-position when the bonding tool 11 is lowered until the lowering rate of the bonding tool 11 reaches or drops below a prescribed value in the lowering process R4.

In the bump bonding process, the controller 60 determines whether or not the bonding of the bump B1 to the chip C is good. The Z-position h1 and the Z-position h2 shown in FIG. 4 are used to determine the goodness of the bump bonding B1. The bonding of the bump B1 being good refers to the bump B1 being bonded to the chip C with a sufficient bonding strength. The bonding of the bump B1 being defective refers to the state in which the bonding strength between the bump B1 and the chip C is insufficient. For example, when the bonding of the bump B1 is defective, the bump B1 easily detaches from the surface of the chip C.

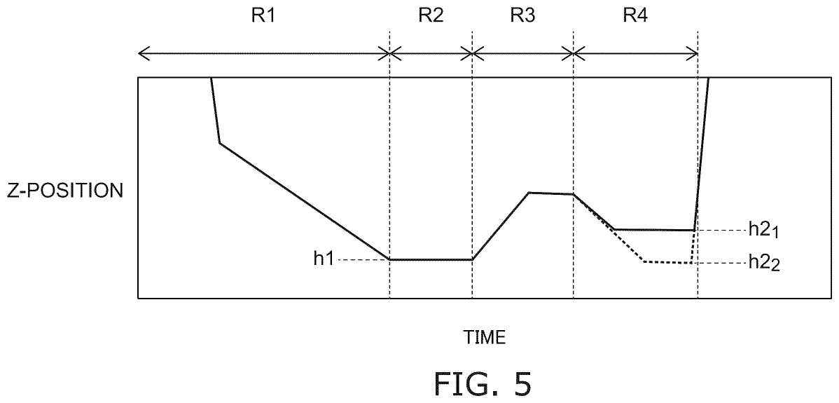

A specific determination method of the goodness will now be described. FIG. 5 is a schematic view showing the change of the Z-position of the bonding tool.

In FIG. 5, the horizontal axis is time, and the vertical axis is the Z-position of the bonding tool 11. The solid line illustrates the change of the Z-position when the bonding of the bump is good. The broken line illustrates the change of the Z-position when the bonding of the bump is defective.

In the example shown in FIG. 5, when the bonding of the bump B1 is good, the bonding tool 11 is lowered to a Z-position h2₁ in the lowering process R4. When the bonding of the bump B1 is defective, the bonding tool 11 is lowered to a Z-position h2₂ in the lowering process R4. The bonding tool 11 is lowered until the prescribed load is detected. That is, the inventors of the application found that the Z-position of the bonding tool 11 when the prescribed load is detected in the case where the bonding is defective is lower than the Z-position of the bonding tool 11 when the prescribed load is detected in the case where the bonding is good. It is considered that the Z-position difference is caused by the difference between the state of the bump B1 in the lowering process R4 when the bonding is good and the state of the bump B1 in the lowering process R4 when the bonding is defective.

Or, the bonding tool 11 may be lowered at a constant speed; and the lowering rate may be detected at that time. When the output of the driver 14 is constant when lowering the bonding tool 11, the lowering rate of the bonding tool 11 decreases when the bonding tool 11 contacts the bump B1. The controller 60 acquires the Z-position of the bonding tool 11 when the lowering rate of the bonding tool 11 reaches or drops below a prescribed value in the lowering process. When the Z-position is acquired based on the lowering rate, the Z-position changes according to the goodness of the bonding. It is considered that the Z-position difference also is caused by the difference between the state of the bump B1 in the lowering process R4 when the bonding is good and the state of the bump B1 in the lowering process R4 when the bonding is defective.

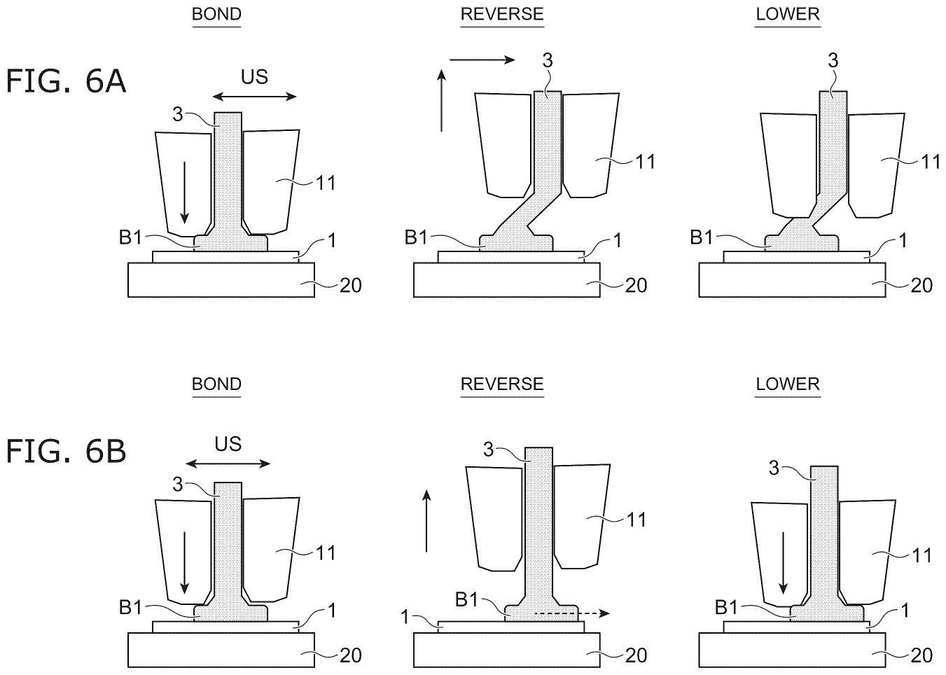

FIG. 6A is a schematic view showing the state of the bump when the bonding is good. FIG. 6B is a schematic view showing the state of the bump when the bonding is defective.

As shown in FIG. 6A, in the reverse process R3 after the bonding process R2, the bonding tool 11 is raised and then moved a preset distance in a preset direction. For example, the bonding tool 11 moves a preset X-direction distance. The movement direction of the bonding tool 11 may be oblique to the horizontal plane. When the bonding is good, the position of the bump B1 bonded to the chip C in the reverse process R3 does not change despite the movement in the X-direction of the bonding tool 11. In the following lowering process R4, the bonding tool 11 is lowered, and the lower end of the bonding tool 11 contacts the seam between the bump B1 and the wire 3. At this time, a load is applied to the bonding tool 11. The prescribed load is detected by the load sensor 40; and the lowering of the bonding tool 11 is stopped. Or, the lowering rate of the bonding tool 11 is reduced when a load is applied to the bonding tool 11. The driver 14 stops lowering the bonding tool 11 when the lowering rate falls below a prescribed value.

On the other hand, the bump B1 easily detaches from the chip C when the bonding is defective. Therefore, as shown in FIG. 6B, it is considered that the position of the bump B1 changes according to the movement in the X-direction of the bonding tool 11 in the reverse process R3. Subsequently, when the bonding tool 11 is lowered in the lowering process R4, the lower end of the bonding tool 11 contacts the side portion of the bump B1 instead of the seam between the bump B1 and the wire 3. When the bonding tool 11 contacts the side portion of the bump B1, a load is applied to the bonding tool 11. The lowering of the bonding tool 11 is stopped based on one of the load on the bonding tool 11 or the lowering rate of the bonding tool 11. Therefore, the Z-position at which the bonding tool 11 stops is lower than the position when the bonding tool 11 contacts the seam between the bump B1 and the wire 3.

The controller 60 determines the goodness of the bump bonding B1 by utilizing the change of the Z-position corresponding to the goodness of the bonding. Specifically, the controller 60 calculates the difference between the Z-position h1 detected in the bonding process R2 and the Z-position (h2₁ or h2₂) detected in the lowering process R4. It can be seen from FIG. 5 that the difference between the Z-position h1 and the Z-position h2₂ is less than the difference between the Z-position h1 and the Z-position h2₁. The controller 60 compares the calculated difference to a preset threshold. The threshold is set to a value that is greater than the difference between the Z-position h1 and the Z-position h2₂ and less than the difference between the Z-position h1 and the Z-position h2₁. When the difference is not less than the threshold, the controller 60 determines that the bonding of the bump B1 is good. When the difference is less than the threshold, the controller 60 determines that the bonding of the bump B1 is defective.

When the bonding of the bump B1 is determined to be defective, the controller 60 stops the wire bonding process. The specific timing of the stop is arbitrary. For example, the controller 60 may stop the wire bonding process immediately when the bonding of the bump B1 is determined to be defective. Or, the controller 60 may stop the wire bonding process after the processes up to the tail cut process R6 are performed. In any case, the subsequent first bonding process is not performed. When the bonding of the bump B1 is determined to be good, the controller 60 performs the subsequent first bonding process and second bonding process.

Advantages of the first embodiment will now be described.

When the bonding of the bump is defective, the bump detaches easily. As a result, a conduction defect or the like of the workpiece occurs. It is therefore desirable to determine the goodness of the bonding after the bump is bonded. The following two methods may be considered as reference examples to determine the goodness of the bonding.

In a first method, the electrical resistance between the bump and the workpiece or the electrostatic capacitance of the workpiece is measured when bonding the bump. When the bonding of the bump is good, the electrical resistance or the electrostatic capacitance changes. The goodness of the bump bonding can be determined based on the change.

In a second method, the Z-position of the bonding tool in the second bonding process is used. The wire contacts the bump in the second bonding process when the bonding of the bump is good and the bump remains at the surface of the chip. If the bonding of the bump is insufficient and the bump does not remain at the surface of the chip, the wire contacts the surface of the chip. In other words, the Z-position of the bonding tool in the second bonding process changes according to the goodness of the bump bonding. Therefore, the goodness of the bump bonding can be determined based on the Z-position of the bonding tool in the second bonding process.

However, in the first method, the goodness of the bump bonding cannot be determined when the workpiece is not conductive or when the electrostatic capacitance of the workpiece is small. In the second method, the goodness of the bonding is determined when bonding the wire after the bump is formed. When the bonding is determined to be defective, a person inspects the bonding of the bump with the naked eye. When the inspection with the naked eye also determines the bonding to be defective, the wire is cut so that the workpiece will be reliably determined to be defective in a subsequent test of the electrical characteristics. Therefore, a task is necessary when a bonding defect occurs.

For these problems, according to the first embodiment, the controller 60 calculates, when bonding the bump B1, the difference between the first position when the bonding tool 11 is lowered most in the bonding process R2 and the second position when the prescribed load is applied to the bonding tool 11 in the lowering process R4. Then, the controller 60 determines the goodness of the bump bonding based on the difference. According to this method, the goodness of the bump bonding can be determined regardless of the electrical characteristics of the workpiece. Also, the goodness of the bump bonding can be determined based on only information obtained in the bump bonding process. In other words, the determination result is obtained at a timing that is earlier than the second bonding process. Therefore, according to the determination result, the first bonding process and the second bonding process can be stopped. Because the first bonding process and the second bonding process are not performed, it is unnecessary to cut the wire before performing the test of the electrical characteristics, and so the task that was necessary when the bonding was defective can be eliminated.

According to the first embodiment, the goodness of the bump bonding can be determined at an earlier timing, regardless of the electrical characteristics of the workpiece.

### Modifications

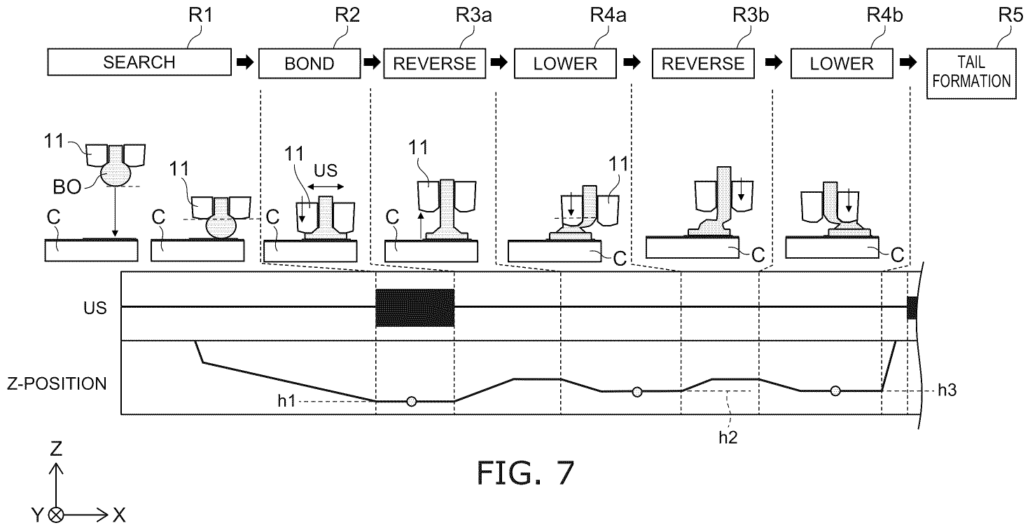

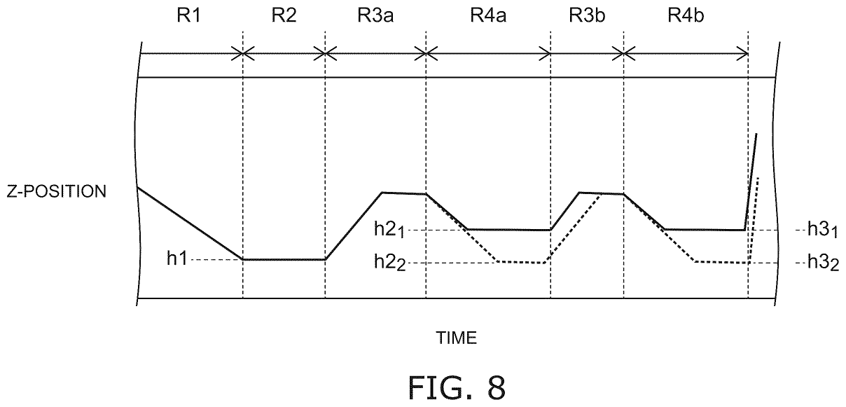

FIG. 7 is a schematic view showing another example of the bump bonding process.

The bump bonding process may include multiple reverse processes R3 and multiple lowering processes R4. In the example shown in FIG. 7, the bump bonding process includes a reverse process R3a, a lowering process R4a, a reverse process R3b, and a lowering process R4b. That is, the reverse process R3 and the lowering process R4 are alternately repeated twice.

In the reverse process R3a, the bonding tool 11 is raised, and then the position of the bonding tool 11 in the horizontal direction (e.g., the X-direction) is changed. In the lowering process R4a, the bonding tool 11 is lowered until the prescribed load is applied to the bonding tool 11. In the reverse process R3b, the bonding tool 11 is raised and then moved in the −X direction. The horizontal direction in which the bonding tool 11 moves in the reverse process R3b is the opposite of the horizontal direction in which the bonding tool 11 moves in the reverse process R3a. Subsequently, in the lowering process R4b, the bonding tool 11 is lowered until the prescribed load is applied to the bonding tool 11. Thereafter, the tail formation process R5, the tail cut process R6, and the spark process R7 are performed similarly to the example shown in FIG. 4.

When multiple lowering processes are performed, the Z-position is detected in each of the lowering processes. For example, as shown in FIG. 7, the Z-position h2 is detected in the lowering process R4a; and a Z-position h3 is detected in the lowering process R4b.

When the bonding of the bump B1 is insufficient, the bump B1 also moves according to the movement in the horizontal direction of the bonding tool 11 as shown in FIG. 5. Therefore, the Z-position of the bonding tool 11 when the prescribed load is applied to the bonding tool 11 in the lowering processes R4a and R4b changes according to the goodness of the bump bonding B1.

FIG. 8 is a schematic view showing the change of the Z-position of the bonding tool.

In FIG. 8, the horizontal axis is time and the vertical axis is the Z-position of the bonding tool 11. The solid line illustrates the change of the Z-position when the bonding of the bump is good. The broken line illustrates the change of the Z-position when the bonding of the bump is defective. For example, as shown in FIG. 8, when the bonding is good, the Z-position h2₁ is detected in the lowering process R4a; and a Z-position h3₁ is detected in the lowering process R4b. When the bonding is defective, the Z-position h2₂ is detected in the lowering process R4a; and a Z-position h3₂ is detected in the lowering process R4b. The Z-position h2₂ is positioned lower than the Z-position h2₁; and the Z-position h3₂ is positioned lower than the Z-position h3₁.

The controller 60 calculates a first difference between the Z-position h1 detected in the bonding process R2 and the Z-position (h2₁ or h2₂) detected in the lowering process R4a. The controller 60 also calculates a second difference between the Z-position h1 and the Z-position (h3₁ or h3₂) detected in the lowering process R4b.

The controller 60 determines the bonding of the bump B1 to be good when the first difference is not less than a prescribed threshold and the second difference is not less than the threshold. The controller 60 determines the bonding of the bump B1 to be defective when the first difference is less than the threshold or when the second difference is less than the threshold.

Or, the controller 60 may determine the bonding of the bump B1 to be good when the first difference is not less than a prescribed threshold and the second difference is not less than a threshold. The controller 60 determines that the bonding of the bump B1 is defective when the first difference is less than the threshold and the second difference is less than the threshold.

When multiple reverse processes R3 and multiple lowering processes R4 are performed, the accuracy of the determination can be further increased by using the Z-positions of the lowering processes R4 to determine the goodness of the bump bonding B1.

### Second Embodiment

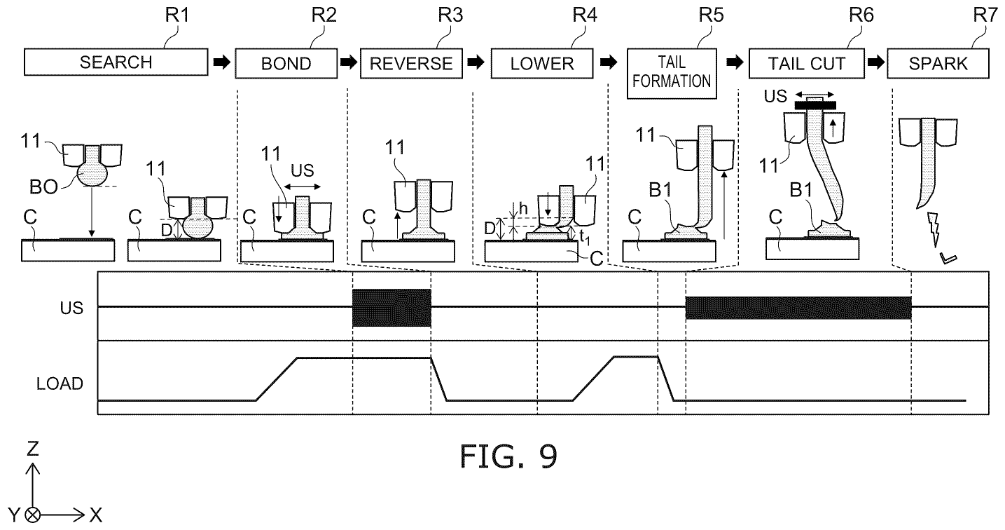

FIG. 9 is a schematic view showing an example of the bump bonding process.

FIGS. 4 and 7 show the Z-position detected in the bump bonding process. In contrast, FIG. 9 shows the load detected in the bump bonding process.

As shown in FIG. 9, a load is applied to the bonding tool 11 in a portion of the search process R1, in the bonding process R2, and in the lowering process R4. The load that is applied to the bonding tool 11 is detected by the load sensor 40. According to the second embodiment, the goodness of the bump bonding B1 is determined based on the load on the bonding tool 11 detected in the lowering process R4.

Specifically, in the lowering process R4 according to the first embodiment, the bonding tool 11 is lowered until the prescribed load is detected. In the lowering process R4 according to the second embodiment, the bonding tool 11 is lowered until the bonding tool 11 reaches a prescribed Z-position. When the bonding of the bump B1 is good, the prescribed Z-position is set to a position such that the bonding tool 11 contacts the bump B1. As shown in FIG. 5, the bonding tool 11 contacts the bump B1 at a higher position when the bonding of the bump B1 is good than when the bonding of the bump B1 is defective. That is, when states are compared in which the bonding tool 11 is at the same Z-position, the load on the bonding tool 11 when the bonding of the bump B1 is good is greater than the load on the bonding tool 11 when the bonding of the bump B1 is defective.

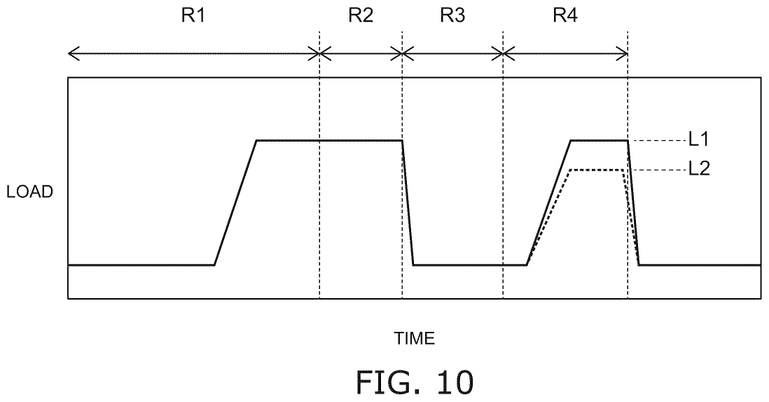

FIG. 10 is a schematic view showing the change of the load on the bonding tool.

In FIG. 10, the horizontal axis is time, and the vertical axis is the load on the bonding tool 11. The solid line illustrates the change of the load when the bonding of the bump is good. The broken line illustrates the change of the load when the bonding of the bump is defective. In the example shown in FIG. 10, a load L1 is detected in the lowering process R4 when the bonding tool 11 reaches the prescribed Z-position when the bonding of the bump B1 is good. A load L2 is detected in the lowering process R4 when the bonding tool 11 reaches the prescribed Z-position when the bonding of the bump B1 is defective. The load L2 is less than the load L1.

The controller 60 compares the load detected in the lowering process R4 to a prescribed threshold. The threshold is set to a value between the load L1 and the load L2. When the detected load is not less than the threshold, the controller 60 determines the bonding to be good. When the detected load is less than the threshold, the controller 60 determines the bonding to be defective. When the bonding of the bump B1 is determined to be defective, the controller 60 stops the wire bonding process.

According to the second embodiment, similarly to the first embodiment, the goodness of the bump bonding can be determined at an earlier timing, regardless of the electrical characteristics of the workpiece.

### Third Embodiment

In the lowering process R4 according to a third embodiment of the invention, the period (the length of time) from the start of the lowering of the bonding tool 11 until the prescribed load is applied to the bonding tool 11 is detected. The controller 60 determines the goodness of the bump bonding B1 based on the period.

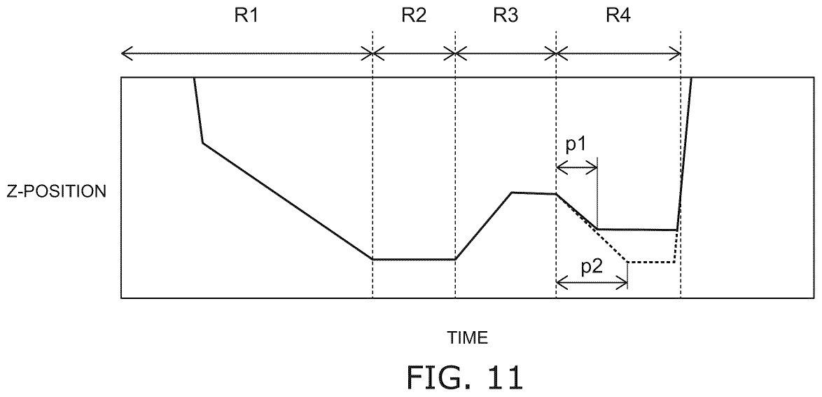

FIG. 11 is a schematic view showing the change of the Z-position of the bonding tool.

In FIG. 11, similarly to FIG. 5, the horizontal axis and the vertical axis are respectively the time and the Z-position. The solid line and the broken line illustrate the change of the Z-position when the bonding of the bump is respectively good and defective. In the example shown in FIG. 11, when the bonding of the bump B1 is good, the length of time from the start of the lowering of the bonding tool 11 in the lowering process R4 until the prescribed load on the bonding tool 11 is detected is a period p1. When the bonding of the bump B1 is defective, the length of time from the start of the lowering of the bonding tool 11 in the lowering process R4 until the prescribed load on the bonding tool 11 is detected is a period p2. The period p2 is greater than the period p1.

The controller 60 compares the detected period to a prescribed threshold. The threshold is set to a value between the period p1 and the period p2. The controller 60 determines the bonding to be good when the detected period is less than the threshold. When the detected period is not less than the threshold, the controller 60 determines the bonding to be defective. The controller 60 stops the wire bonding process when the bonding of the bump B1 is determined to be defective.

According to the third embodiment, similarly to the first embodiment, the goodness of the bump bonding can be determined at an earlier timing, regardless of the electrical characteristics of the workpiece.

A bump bonding process such as that shown in the modification of the first embodiment in which multiple reverse processes R3 and multiple lowering processes R4 are performed also is applicable to the second embodiment or third embodiment above.

According to the embodiments of the invention described above, the controller 60 can determine the goodness of the bump bonding at the first bonding point based on the prescribed detected value detected in the lowering process R4.

According to the first embodiment, “the prescribed detected value” is the second position of the bonding tool 11 when the prescribed load is applied to the bonding tool 11 in the lowering process R4. The controller 60 acquires the first position of the bonding tool 11 when the bonding tool 11 is lowered most in the bonding process R2. The controller 60 determines the goodness of the bump bonding B1 by comparing the difference between the first position and the second position to a preset threshold.

According to the second embodiment, “the prescribed detected value” is the load on the bonding tool 11 when the bonding tool 11 is lowered to the prescribed position in the lowering process R4. The controller 60 determines the goodness of the bump bonding B1 by comparing the load to the preset threshold.

According to the third embodiment, “the prescribed detected value” is the period from the start of the lowering process R4 until the prescribed load is applied to the bonding tool 11. The controller 60 determines the goodness of the bump bonding B1 by comparing the period to the preset threshold.

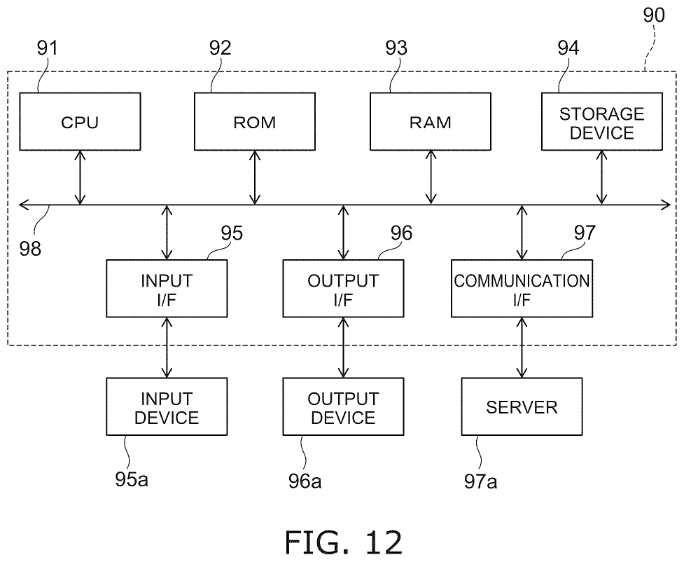

FIG. 12 is a schematic view illustrating a hardware configuration.

For example, a computer 90 shown in FIG. 12 is used as the controller 60. The computer 90 includes a CPU 91, ROM 92, RAM 93, a storage device 94, an input interface 95, an output interface 96, and a communication interface 97.

The ROM 92 stores programs controlling operations of the computer 90. The ROM 92 stores programs necessary for causing the computer 90 to realize the processing described above. The RAM 93 functions as a memory region into which the programs stored in the ROM 92 are loaded.

The CPU 91 includes a processing circuit. The CPU 91 uses the RAM 93 as work memory to execute the programs stored in at least one of the ROM 92 or the storage device 94. When executing the programs, the CPU 91 executes various processing by controlling configurations via a system bus 98.

The storage device 94 stores data necessary for executing the programs and/or data obtained by executing the programs.

The input interface (I/F) 95 can connect the computer 90 and an input device 95a. The input I/F 95 is, for example, a serial bus interface such as USB, etc. The CPU 91 can read various data from the input device 95a via the input I/F 95.

The output interface (I/F) 96 can connect the computer 90 and an output device 96a. The output I/F 96 is, for example, an image output interface such as Digital Visual Interface (DVI), High-Definition Multimedia Interface (HPMI (registered trademark)), etc. The CPU 91 can transmit data to the output device 96a via the output I/F 96 and cause the output device 96a to display an image.

The communication interface (I/F) 97 can connect the computer 90 and a server 97a outside the computer 90. The communication I/F 97 is, for example, a network card such as a LAN card, etc. The CPU 91 can read various data from the server 97a via the communication I/F 97.

The storage device 94 includes at least one selected from a hard disk drive (HDD) and a solid state drive (SSD). The input device 95a includes at least one selected from a mouse, a keyboard, a microphone (audio input), and a touchpad. The output device 96a includes at least one selected from a monitor, a projector, a printer, and a speaker. A device such as a touch panel that functions as both the input device 95a and the output device 96a may be used.

The processing that is performed by the controller 60 may be realized by one computer 90 and may be realized by collaboration of multiple computers 90.

The processing of the various data described above may be recorded, as a program that can be executed by a computer, in a magnetic disk (a flexible disk, a hard disk, etc.), an optical disk (CD-ROM, CD-R, CD-RW, DVD-ROM, DVD+R, DVD+RW, etc.), semiconductor memory, or another non-transitory computer-readable storage medium.

For example, the information that is recorded in the recording medium can be read by a computer (or an embedded system). The recording format (the storage format) of the recording medium is arbitrary. For example, the computer reads a program from the recording medium and causes a CPU to execute the instructions recited in the program based on the program. In the computer, the acquisition (or the reading) of the program may be performed via a network.

The embodiments of the invention include the following features.

### Feature 1

A wire bonding apparatus, including:
a bonding tool configured to feed a wire;
a driver configured to drive the bonding tool; and
a controller configured to control the bonding tool and the driver,
the controller performing at least
   a bonding process of causing a ball formed at a tip of the wire to contact a first bonding point, deforming the ball into a bump, and bonding the bump to the first bonding point, and
   a lowering process of raising the bonding tool while the bonding tool holds the wire connected with the bump, changing a position of the bonding tool in a horizontal direction, and subsequently lowering the bonding tool toward the first bonding point,
the controller determining a goodness of the bonding of the bump to the first bonding point based on a detected value detected in the lowering process,
the detected value being prescribed.

### Feature 2

The wire bonding apparatus according to feature 1, in which
the detected value includes at least one selected from:
   a position of the bonding tool when a prescribed load is applied to the bonding tool in the lowering process;
   a position of the bonding tool when a lowering rate of the bonding tool changes to be not more than a prescribed value in the lowering process;
   a load on the bonding tool when the bonding tool is lowered to a prescribed position in the lowering process; and
   a period from a start of the lowering process until a prescribed load is applied to the bonding tool.

### Feature 3

The wire bonding apparatus according to feature 1, in which
the controller acquires a first position when the bonding tool is lowered most in the bonding process,
the detected value includes a second position of the bonding tool when a prescribed load is applied to the bonding tool in the lowering process, and
the controller determines that the bonding of the bump is defective in the case where a difference between the first position and the second position is less than a preset threshold.

The wire bonding apparatus according to any one of features 1 to 3, in which

### Feature 4

in the case where the bonding of the bump is determined to be good, the controller performs at least a first bonding process of moving the bonding tool above a second bonding point, lowering the bonding tool with a ball formed at the tip of the wire, and causing the ball to contact the second bonding point, and
in the case where the bonding of the bump is determined to be defective, the controller does not perform the first bonding process.

### Feature 5

A control device configured to control a wire bonding apparatus,
the wire bonding apparatus including:
   a bonding tool configured to feed a wire; and
   a driver driving the bonding tool,
the control device being configured to cause the wire bonding apparatus to perform at least:
   a bonding process of causing a ball formed at a tip of the wire to contact a first bonding point, deforming the ball into a bump, and bonding the bump to the first bonding point; and
   a lowering process of raising the bonding tool while the bonding tool holds the wire connected with the bump, changing a position of the bonding tool in a horizontal direction, and subsequently lowering the bonding tool toward the first bonding point,
the control device determining a goodness of the bonding of the bump to the first bonding point based on a detected value detected in the lowering process,
the detected value being prescribed.

### Feature 6

A control method of a wire bonding apparatus,
the wire bonding apparatus including:
   a bonding tool configured to feed a wire; and
   a driver configured to drive the bonding tool,
the control method including causing the wire bonding apparatus to perform at least:
   a bonding process of causing a ball formed at a tip of the wire to contact a first bonding point, deforming the ball into a bump, and bonding the bump to the first bonding point; and
   a lowering process of raising the bonding tool while the bonding tool holds the wire connected with the bump, changing a position of the bonding tool in a horizontal direction, and subsequently lowering the bonding tool toward the first bonding point,
the control method further including determining a goodness of the bonding of the bump to the first bonding point based on a detected value detected in the lowering process,
the detected value being prescribed.

According to the embodiments above, a wire bonding apparatus is provided that can determine the goodness of the bump bonding at an earlier timing, regardless of the electrical characteristics of the workpiece. Also, by performing the determination method of the goodness of the bonding described above in the bump bonding process, the controller (the control device) can determine the goodness of the bump bonding at an earlier timing, regardless of the electrical characteristics of the workpiece. According to the control method performed by the controller described above, the goodness of the bump bonding can be determined at an earlier timing, regardless of the electrical characteristics of the workpiece.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A wire bonding apparatus, comprising:
a bonding tool configured to feed a wire;
a driver configured to drive the bonding tool; and
a controller configured to control the bonding tool and the driver,
the controller performing at least
a bonding process of causing a ball formed at a tip of the wire to contact a first bonding point, deforming the ball into a bump, and bonding the bump to the first bonding point, and
a lowering process of raising the bonding tool while the bonding tool holds the wire connected with the bump, changing a position of the bonding tool in a horizontal direction, and subsequently lowering the bonding tool toward the first bonding point,
the controller determining a goodness of the bonding of the bump to the first bonding point based on a detected value detected in the lowering process,
the detected value being prescribed.

2. The wire bonding apparatus according to claim 1, wherein the detected value includes at least one selected from:
a position of the bonding tool when a prescribed load is applied to the bonding tool in the lowering process;
a position of the bonding tool when a lowering rate of the bonding tool changes to be not more than a prescribed value in the lowering process;
a load on the bonding tool when the bonding tool is lowered to a prescribed position in the lowering process; and
a period from a start of the lowering process until a prescribed load is applied to the bonding tool.

3. The wire bonding apparatus according to claim 1, wherein the controller acquires a first position when the bonding tool is lowered most in the bonding process,
the detected value includes a second position of the bonding tool when a prescribed load is applied to the bonding tool in the lowering process, and
the controller determines that the bonding of the bump is defective in the case where a difference between the first position and the second position is less than a preset threshold.

4. The wire bonding apparatus according to claim 1, wherein
in the case where the bonding of the bump is determined to be good, the controller performs at least a first bonding process of moving the bonding tool above a second bonding point, lowering the bonding tool with a ball formed at the tip of the wire, and causing the ball to contact the second bonding point, and
in the case where the bonding of the bump is determined to be defective, the controller does not perform the first bonding process.

5. A control device configured to control a wire bonding apparatus,
the wire bonding apparatus including:
a bonding tool configured to feed a wire; and
a driver driving the bonding tool,
the control device being configured to cause the wire bonding apparatus to perform at least:
a bonding process of causing a ball formed at a tip of the wire to contact a first bonding point, deforming the ball into a bump, and bonding the bump to the first bonding point; and
a lowering process of raising the bonding tool while the bonding tool holds the wire connected with the bump, changing a position of the bonding tool in a horizontal direction, and subsequently lowering the bonding tool toward the first bonding point,
the control device determining a goodness of the bonding of the bump to the first bonding point based on a detected value detected in the lowering process,
the detected value being prescribed.

6. A control method of a wire bonding apparatus,
the wire bonding apparatus including:
a bonding tool configured to feed a wire; and
a driver configured to drive the bonding tool,
the control method comprising causing the wire bonding apparatus to perform at least:
a bonding process of causing a ball formed at a tip of the wire to contact a first bonding point, deforming the ball into a bump, and bonding the bump to the first bonding point; and
a lowering process of raising the bonding tool while the bonding tool holds the wire connected with the bump, changing a position of the bonding tool in a horizontal direction, and subsequently lowering the bonding tool toward the first bonding point,
the control method further comprising determining a goodness of the bonding of the bump to the first bonding point based on a detected value detected in the lowering process,
the detected value being prescribed.
